(19) United States
(12) Patent Application Publication
(10) Pub. No.: US 2025/0224786 A1
(43) Pub. Date: Jul. 10, 2025

(54) ELECTRONIC DEVICE COMPRISING THERMOELECTRIC COOLER

(71) Applicant: SAMSUNG ELECTRONICS CO., LTD., Suwon-si (KR)

(72) Inventors: Yoonsun PARK, Suwon-si (KR); Seunghoon Kang, Suwon-si (KR); Hajoong Yun, Suwon-si (KR); Seunga Yi, Suwon-si (KR); Hyeran Jung, Suwon-si (KR)

(73) Assignee: SAMSUNG ELECTRONICS CO., LTD., Suwon-si (KR)

(21) Appl. No.: 19/092,284

(22) Filed: Mar. 27, 2025

Related U.S. Application Data
(63) Continuation of application No. PCT/KR2023/014838, filed on Sep. 26, 2023.

(30) Foreign Application Priority Data
Sep. 28, 2022 (KR) 10-2022-0123252
Oct. 6, 2022 (KR) 10-2022-0127846

(51) Int. Cl. G06F 1/20; G06F 1/16

(52) U.S. Cl. CPC G06F 1/203; G06F 1/1652

(57) ABSTRACT

An electronic device including: a first housing; a second housing; a hinge connecting the first housing and the second housing; an electrical element inside the first housing; a first plate inside the first housing and contacting a surface of the electrical element; at least one thermoelectric cooler inside the second housing and including a cold side contacting the first plate; a second plate inside the second housing and contacting a hot side of the at least one thermoelectric cooler; a memory storing one or more instructions; and one or more processors configured to execute the one or more instructions to: measure a temperature at a specified point of the electrical element or at one or more locations of the first housing where the electrical element is located; and drive the at least one thermoelectric cooler based on the temperature to move heat from the electrical element to the second plate.

### CROSS-REFERENCE TO RELATED APPLICATIONS

This application is a continuation application of International Application No. PCT/KR2023/014838, filed on Sep. 26, 2023, in the Korean Intellectual Property Receiving Office, which claims priority to Korean Patent Application No. 10-2022-0123252, filed on Sep. 28, 2022, and Korean Patent Application No. 10-2022-0127846, filed on Oct. 6, 2022, in the Korean Intellectual Property Office, the disclosures of which are incorporated by reference herein in their entireties.

### BACKGROUND

### 1. Field

The disclosure relates to an electronic device including a thermoelectric cooler.

### 2. Description of Related Art

Electronic devices such as smartphones or tablet personal computers (PCs) may perform functions such as making calls, playing videos, playing music, or playing games. Electronic devices may generate heat as they perform their functions. For example, in a process of executing a game application, the temperature may rapidly rise around a point where an application processor is mounted. When the temperature of the electronic device rises, it may cause burns to a user, and may cause malfunction due to damage to internal components of the electronic device. In foldable electronic devices, heat dissipation may be concentrated in a certain region due to a hinge structure for folding.

A thermoelectric cooler (TEC) may convert electrical energy into a temperature difference. For example, the thermoelectric cooler may be implemented by connecting an “N” type semiconductor in series with an electron-deficient “P” type semiconductor. When direct current (DC) power is applied to both ends of a thermoelectric cooler, with “+” applied to the “N” type semiconductor and “−” applied to the “P” type semiconductor, electrons may flow from the “P” type semiconductor to the cold junction and then to the “N” type semiconductor through a conductor. In this process, heat may be transferred to the “N” type semiconductor by the Peltier effect.

When current flows through the thermoelectric cooler by a DC power supply, heat moves from a cold side (or heat-absorbing portion) of the thermoelectric cooler to a hot side (or heat-generating portion) according to the Peltier effect. The cold side and hot side of the thermoelectric cooler may be determined by a connection direction of the DC power supply.

The thermoelectric cooler may be used in devices requiring heat removal ranging from milliwatts to kilowatts. The cold side of the thermoelectric cooler may be connected to a component that generates heat, and the hot side of the thermoelectric cooler may be connected to a heat sink. This allows the heat from the heat generating component to be quickly dissipated through the heat sink.

Since thermoelectric coolers are operated using electrical energy, their temperature rises when they are driven. Thermoelectric coolers may be applied to devices equipped with a forced convection open system, such as a heat sink, which facilitates cooling on a hot side, or devices where temperature rise of the hot side is not a problem.

In the thermoelectric cooler, a cold side is attached to a heat generating component to cool the heat generating component. In this case, although the cold side helps to directly cool the heat generating component, the amount of the generated heat of the device may increase due to an increase in temperature of a hot side as a whole.

Performance improvement of the thermoelectric cooler may be expected by quickly spreading the heat that is inevitably generated during operation to the surface to improve AP junction heat generation. The thermoelectric cooler may be implemented with components made of materials having high thermal conductivity to improve heat generation at the AP junction or surface, but there is a limit to heat spreading due to the limitations of thermal conductivity.

### SUMMARY

According to an aspect of the disclosure, an electronic device includes: a first housing; a second housing; a hinge connecting the first housing and the second housing to be foldable relative to each other; an electrical element inside the first housing; a first plate inside the first housing and contacting a surface of the electrical element; at least one thermoelectric cooler inside the second housing and including a cold side contacting the first plate; a second plate inside the second housing and contacting a hot side of the at least one thermoelectric cooler; a memory storing one or more instructions; and one or more processors configured to execute the one or more instructions to: measure a temperature at a specified point of the electrical element or at one or more specific locations of the first housing at which the electrical element is located; and drive the at least one thermoelectric cooler based on the temperature to move heat generated in the electrical element to the second plate.

The one or more processors may be further configured to execute the one or more instructions to drive the at least one thermoelectric cooler based on a preset reference temperature compared to the temperature.

The first plate may include: a plate portion contacting the one surface of the electrical element; and a connecting portion extending from the plate portion and contracting the cold side of the at least one thermoelectric cooler.

The connecting portion may include a step, and the plate portion and the second plate may be on a same plane via the step.

A width of the connecting portion may be less than a width of the plate portion.

The at least one thermoelectric cooler may include a plurality of thermoelectric coolers.

The first plate may include: a plate portion contacting the surface of the electrical element; and a connecting portion extending from the plate portion and contacting the cold side. The plurality of thermoelectric coolers may be in a region corresponding to the connecting portion.

The plurality of thermoelectric coolers may be in a region corresponding to an entire end of the second plate adjacent to the hinge in the second plate.

The plurality of thermoelectric coolers may be in a plurality of lines.

The one or more processors may be further configured to execute the one or more instructions to: drive some of the plurality of thermoelectric coolers based on a first reference temperature compared to the temperature; and drive other of the plurality of thermoelectric coolers based on a second reference temperature compared to the temperature.

The one or more processors may be further configured to execute the one or more instructions to drive the at least one thermoelectric cooler in a state in which a specified application is executed by the electronic device.

According to another aspect of the disclosure, an electronic device includes: a first housing; a second housing; a hinge connecting the first housing and the second housing to be foldable relative to each other; an electrical element inside the first housing; a heat dissipation layer configured to dissipate heat generated in the electrical element; a memory including one or more instructions; and one or more processors configured to execute the one or more instructions. The heat dissipation layer includes: a first plate inside the first housing and contacting a surface of the electrical element; at least one thermoelectric cooler inside the second housing and including a cold side contacting the first plate; and a second plate inside the second housing and contacting a hot side of the at least one thermoelectric cooler. The one or more processors are configured to execute the one or more instructions to: measure a temperature at a specified point of the electrical element or at one or more specific locations of the first housing at which the electrical element is located; and drive the at least one thermoelectric cooler based on the temperature to move heat generated in the electrical element to the second plate.

The one or more processors may be further configured to execute the one or more instructions to drive the at least one thermoelectric cooler based on a preset reference temperature compared to the temperature.

The first plate may include: a plate portion contacting the surface of the electrical element; and a connecting portion extending from the plate portion and contacting the cold side of the at least one thermoelectric cooler.

The at least one thermoelectric cooler may include a plurality of thermoelectric coolers.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an electronic device in a network environment according to various embodiments;

FIG. 2 illustrates an electronic device according to one or more embodiments;

FIG. 3 illustrates a heat dissipation structure of an electronic device according to one or more embodiments;

FIG. 4 is a flowchart showing a method of driving a thermoelectric cooler according to one or more embodiments;

FIG. 5 illustrates a change in temperature distribution according to the operation of the thermoelectric cooler according to one or more embodiments;

FIG. 6 shows graphs of temperature changes according to the operation of the thermoelectric cooler according to one or more embodiments;

FIG. 7 illustrates a driving performance of the thermoelectric cooler according to one or more embodiments;

FIG. 8 illustrates a heat dissipation structure including a plurality of thermoelectric coolers according to one or more embodiments;

FIG. 9 illustrates a driving performance of the plurality of thermoelectric coolers according to one or more embodiments;

FIG. 10 shows graphs of temperature changes according to the operation of the plurality of thermoelectric coolers according to one or more embodiments; and

FIG. 11 illustrates a heat dissipation structure including a plurality of thermoelectric coolers with an expanded disposition region according to one or more embodiments.

### DETAILED DESCRIPTION

Hereinafter, various embodiments of the present disclosure will be described with reference to the accompanying drawings. However, this is not intended to limit the present disclosure to the specific embodiments, and it is to be construed to include various modifications, equivalents, and/or alternatives of embodiments of the present disclosure. With regard to the description of the drawings, similar reference numerals may be used to refer to similar elements.

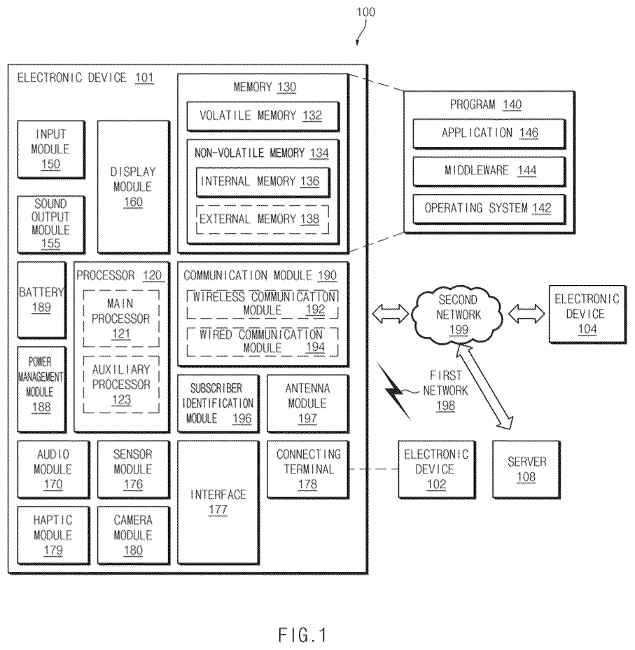

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to one or more embodiments, the electronic device 101 may communicate with the electronic device 104 via the server 108. According to one or more embodiments, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to one or more embodiments, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to one or more embodiments, the auxiliary processor 123 (e.g., an image signal processor or a communication processor) may be implemented as part of another component (e.g., the camera module 180 or the communication module 190) functionally related to the auxiliary processor 123. According to one or more embodiments, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to one or more embodiments, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to one or more embodiments, the display module 160 may include a touch sensor adapted to detect a touch, or a pressure sensor adapted to measure the intensity of force incurred by the touch.

The audio module 170 may convert a sound into an electrical signal and vice versa. According to one or more embodiments, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to one or more embodiments, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to one or more embodiments, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to one or more embodiments, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to one or more embodiments, the haptic module 179 may include, for example, a motor, a piezoelectric element, or an electric stimulator.

The camera module 180 may capture a still image or moving images. According to one or more embodiments, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to one or more embodiments, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to one or more embodiments, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to one or more embodiments, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to one or more embodiments, the antenna module 197 may include an antenna including a radiating element composed of a conductive material or a conductive pattern formed in or on a substrate (e.g., a printed circuit board (PCB)). According to one or more embodiments, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to one or more embodiments, another component (e.g., a radio frequency integrated circuit (RFIC)) other than the radiating element may be additionally formed as part of the antenna module 197.

According to various embodiments, the antenna module 197 may form a mmWave antenna module. According to one or more embodiments, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) there between via an inter-peripheral communication scheme (e.g., a bus, general purpose input and output (GPIO), serial peripheral interface (SPI), or mobile industry processor interface (MIPI)).

According to one or more embodiments, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to one or more embodiments, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an internet-of-things (IoT) device. The server 108 may be an intelligent server using machine learning and/or a neural network. According to one or more embodiments, the external electronic device 104 or the server 108 may be included in the second network 199. The electronic device 101 may be applied to intelligent services (e.g., smart home, smart city, smart car, or healthcare) based on 5G communication technology or IoT-related technology.

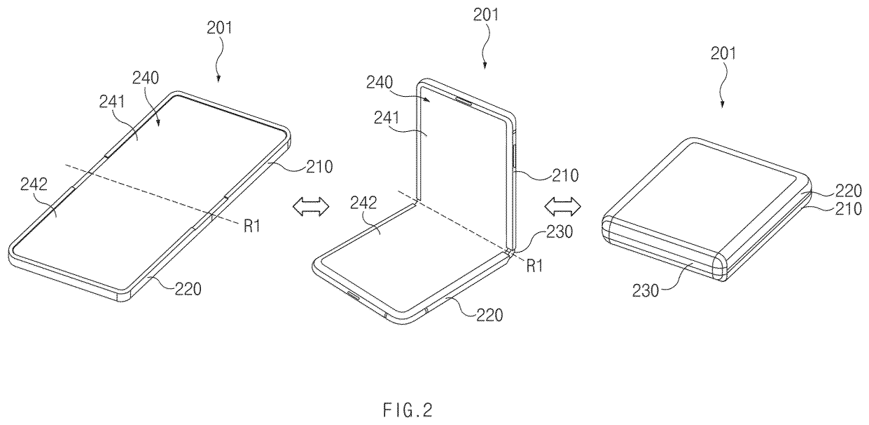

FIG. 2 illustrates an electronic device according to one or more embodiments. FIG. 2 illustrates an example of a foldable electronic device in a flip manner (folded in an up-down direction), but embodiments of the disclosure are not limited thereto.

Referring to FIG. 2, an electronic device 201 may include a first housing 210, a second housing 220, a hinge structure 230, and a display (or flexible display, foldable display) 240. The first housing 210 and the second housing 220 may be folded or unfolded based on a center R1 of the hinge structure 230.

When the electronic device 201 is fully unfolded (hereinafter, a fully unfolded state), an angle between the first housing 210 and the second housing 220 may be 180 degrees. In this case, the display 240 may be in a substantially flat state.

When the electronic device 201 is partially folded (or partially unfolded) (hereinafter, a partially folded state), an angle between the first housing 210 and the second housing 220 may be greater than 0 degrees and less than 180 degrees. In this case, the display 240 may be folded to form a specified angle, and a specified mode or a specified application may be executed.

When the electronic device 201 is fully folded (hereinafter, a fully folded state), the angle between the first housing 210 and the second housing 220 may be 0 degrees. The display 240 may be invisible from the outside.

The hinge structure 230 may be at least partially exposed to the outside of the electronic device 201 in a partially folded state and a fully folded state to form the exterior (or surface) of the electronic device 201. For example, the hinge structure 230 may be visually exposed between the first housing 210 and the second housing 220 when the electronic device 201 is in the partially folded or fully folded state. The hinge structure 230 may be covered by the first housing 210 and the second housing 220 when the electronic device 201 is fully unfolded, and may not be exposed to the outside of the electronic device 201. However, without being limited to the illustrated embodiment, the electronic device 201 may be configured such that at least a portion of the hinge structure 230 is exposed when in the fully unfolded state.

The display 240 may be folded or unfolded based on the center R1 of the hinge structure 230. The display 240 may include a first display portion 241 disposed in the first housing 210 and a second display portion 242 disposed in the second housing 220.

In the fully unfolded state, the display 240 may be substantially flat. In the partially folded state, the display 240 may be folded to form a specified angle. In the fully folded state, the display 240 may be invisible from the outside.

According to one or more embodiments, the electronic device 201 may include various components or parts therein. The electronic device 201 may include components such as a processor (e.g., the processor 120 in FIG. 1), a memory (e.g., the memory 130 in FIG. 1), a communication circuit (e.g., the communication module 190 in FIG. 1), a printed circuit board, a battery (e.g., the battery 189 in FIG. 1), and a sensor (e.g., the sensor module 176 in FIG. 1).

According to one or more embodiments, in the electronic device 201, heat may be generated by heat generating elements (or electrical elements) that are centrally disposed in one of the first housing 210 or the second housing 220. In this case, a thermal spreading bottle neck may occur around the hinge structure 230. The electronic device 201 may include a heat dissipation structure (or cooling structure) including a thermoelectric cooler therein. The heat dissipation structure including the thermoelectric cooler may reduce or spread heat generated in the heat generating element. Additional information regarding the heat dissipation structure including the thermoelectric cooler may be provided through the drawings below. Below, the discussion will focus on a form in which the heat generating element is included inside the first housing 210 and the thermoelectric cooler is included inside the second housing 220, but embodiments of the disclosure are not limited thereto.

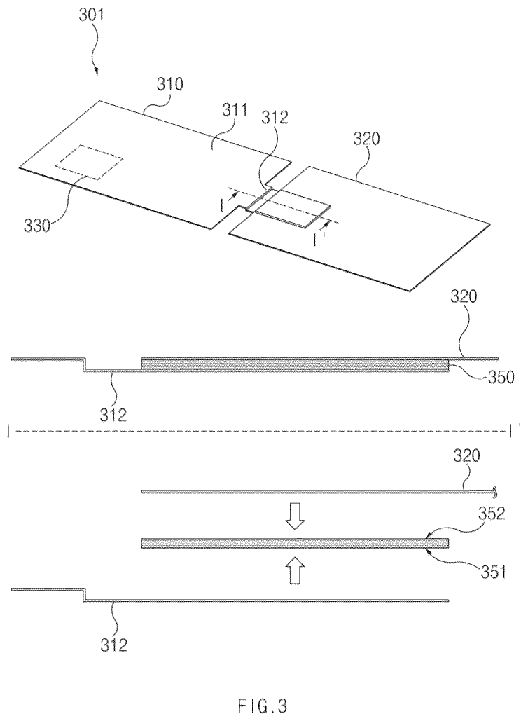

FIG. 3 illustrates a heat dissipation structure of an electronic device according to one or more embodiments.

Referring to FIGS. 2 and 3, a heat dissipation layer 301 may include a first plate 310, a second plate 320, a heat generating element 330, and a thermoelectric cooler 350. The heat dissipation layer 301 may be included inside the electronic device 101 in FIG. 1 or the electronic device 201 in FIG. 2.

The first plate (or a first heat-conducting panel) 310 may transfer heat generated in the heat generating element 330 to a cold side 351 of the thermoelectric cooler 350. The first plate 310 may be implemented with a material or shape having high thermal conductivity. For example, the first plate 310 may be implemented with graphite, a metal material (Cu, SUS, or the like), or a water-cooled heat dissipation member (a heat pipe, vapor chamber, or the like).

The first plate 310 may include a plate portion 311 and a connecting portion 312. The plate portion 311 and the connecting portion 312 may be integrally formed and made of the same material.

The plate portion 311 may be included in the first housing 210. At least a portion of the plate portion 311 may come into contact with the heat generating element 330. For example, the plate portion 311 may be bonded to the heat generating element 330 through thermal grease.

The connecting portion 312 may be connected to an end of the plate portion 311 adjacent to the hinge structure 230. The connecting portion 312 may have a narrower width than the plate portion 311. The connecting portion 312 may contact the cold side 351 of the thermoelectric cooler 350 through the interior of the hinge structure 230. The connecting portion 312 may include a step, and the plate portion 311 and the second plate 320 may be disposed at the same height or similar heights by the step. The plate portion 311 and the connecting portion 312 may transfer heat generated in the heat generating element 330 to the thermoelectric cooler 350.

According to one or more embodiments, the plate portion 311 may be implemented in a form that forms an internal space, such as a heat pipe or vapor chamber. In this case, the connecting portion 312 may be formed as a single panel, unlike the plate portion 311, and one of the panels constituting the plate portion 311 may be in an extended form.

According to one or more embodiments, the thicknesses of the plate portion 311 and the connecting portion 312 may be different from each other. For example, the thickness of the plate portion 311 may be thinner than the thickness of the connecting portion 312. For another example, the thickness of the connecting portion 312 may be thinner than the thickness of the plate portion 311.

The second plate (or second heat-conducting panel) 320 may be included in the second housing 220. The second plate 320 may contact a hot side 352 of the thermoelectric cooler 350 at a point adjacent to the hinge structure 230. The second plate 320 may diffuse or dissipate heat transferred through the thermoelectric cooler 350. The second plate 320 may be implemented with a material or shape having high thermal conductivity. For example, the second plate 320 may be implemented with graphite, a metal material (Cu, SUS, or the like), or a water-cooled heat dissipation member (a heat pipe, vapor chamber, or the like).

The heat generating element 330 may be an electrical element that generates heat with the operation of the electronic device 201. For example, the heat generating element 330 may be an application processor (AP). The heat generating element 330 may be included inside the first housing 210. One side of the heat generating element 330 may come into contact with the plate portion 311 of the first plate 310. The other side of the heat generating element 330 may be attached to a printed circuit board. Heat generated in the heat generating element 330 may be transferred to the thermoelectric cooler 350 through the first plate 310.

The thermoelectric cooler 350 may be included inside the second housing 220. The thermoelectric cooler 350 may include the cold side 351 and the hot side 352. The cold side 351 may be disposed to face a front surface of the electronic device 201 (a surface where the display 240 is exposed in the fully unfolded state). The hot side 352 may be disposed to face a back surface of the electronic device 201 (a surface opposite to the surface where the display 240 is exposed in the fully unfolded state). The thermoelectric cooler 350 may be implemented in a thin form and may be implemented with a specified thickness (e.g., 1.8×2.4×0.75 T).

The cold side 351 of the thermoelectric cooler 350 may be in contact with the connecting portion 312 of the first plate 310. The hot side 352 of the thermoelectric cooler 350 may be in contact with the second plate 320. The thermoelectric cooler 350 may be disposed in a housing different from the heat generating element 330. In FIG. 3, a form in which the heat generating element 330 is included in the first housing 210 and the thermoelectric cooler 350 is included in the second housing 220 is illustrated, but embodiments of the disclosure are not limited thereto. For example, the electronic device 201 may be implemented in a form in which the heat generating element 330 is included in the second housing 220 and the thermoelectric cooler 350 is included in the first housing 210.

Thermoelectric cooler 350 may increase the heat transfer amount of the heat dissipation layer 301 to disperse the heat of heat generating element 330. The thermoelectric cooler 350 may increase the heat transfer amount by increasing a temperature difference ΔT between the first plate 310 and the second plate 320 having the same thermal conductivity.

For example, thermal conductivities of the first plate 310 and the second plate 320 may be calculated using the following [Equation 1], and the thermoelectric cooler 350 may increase the heat transfer amount by increasing the temperature difference ΔT between the first plate 310 and the second plate 320.

$${\dot{Q}}_{cd} = kA \frac{{T}_{1} - {T}_{2}}{Δ x} = - kA \frac{Δ T}{Δ x} \qquad [ Equation 1 ]$$

\dot{Q}_{cd}: Heat transfer amount
k: Thermal conductivity
A: Cross-sectional area
Δx: Heat transfer distance

According to one or more embodiments, the movement of heat in the thermoelectric cooler 350 is naturally accompanied by resistive heat (Joule heat) release from both sides and heat flux from a hot junction to a cold junction (an effect opposite to the Peltier effect). The dissipation of resistive heat depends on the electrical resistance of the current and the thermoelectric cooler itself, while the heat flux depends on the temperature difference between the two sides and the thermal conductivity of the thermoelectric cooler. The net cooling heat amount of the thermoelectric cooler 350 may be calculated using the following [Equation 2].

$$Qc = Qs - Qf - Qj \qquad [ Equation 2 ]$$

Qc: Net cooling heat amount of thermoelectric cooler
Qs: Cooling heat amount of thermoelectric cooler
Qj: Joule heat due to in-element current in thermoelectric cooler
Qf: Conduction heat (heat loss due to heat conduction from high temperature portion to low temperature portion)

The increase in heat transfer due to the operation of the thermoelectric cooler 350 may lower the maximum temperature of the surface of the electronic device 201 and increase the average temperature. Thereby, a coefficient of thermal spreading (CTS), which is a ratio between the maximum temperature and the average temperature of the surface, may be increased. The CTS may be calculated using the following [Equation 3].

$$CTS = θ ave / θ max = ( Tave - Tambient ) / ( Tmax - Tambient ) \qquad [ Equation 3 ]$$

Tave: Average temperature of surface
Tmax: Maximum temperature of surface
Tambient: Ambient temperature

When the CTS is 1, the heat spreading state is the most ideal.

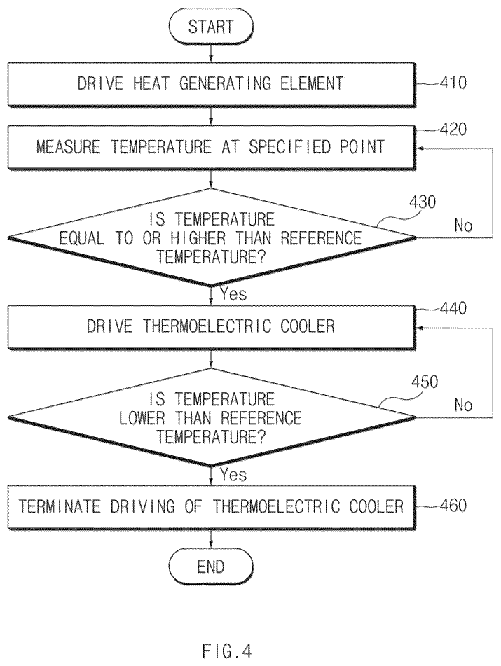

FIG. 4 is a flowchart showing a method of driving a thermoelectric cooler according to one or more embodiments.

Referring to FIGS. 1 to 4, in operation 410, the processor 120 may execute a specified function (e.g., video playback, game execution) using the heat generating element 330. For example, the heat generating element 330 may be an application processor (AP) or a communication chip. Alternatively, the heat generating element 330 may be identical to the processor 120.

In operation 420, the processor 120 may measure the temperature of the heat generating element 330 (or a surface adjacent to the heat generating element 330). The processor 120 may measure the temperature of a surface adjacent to the heat generating element 330 through a temperature sensor disposed adjacent to the heat generating element 330. Alternatively, the processor 120 may measure the temperature through a T-sensor inside the heat generating element 330.

In operation 430, the processor 120 may check whether the measured temperature is equal to or higher than (or exceeds) a reference temperature. For example, the processor 120 may check whether a junction temperature of the application processor or CPU is equal to or higher than 70 degrees, which is the reference temperature. For another example, the processor 120 may check whether the temperature of a surface adjacent to the heat generating element 330 is equal to or higher than 40 degrees, which is the reference temperature.

In operation 440, the processor 120 may drive the thermoelectric cooler 350 when the measured temperature is equal to or higher than (or exceeds) the reference temperature (YES in 430). The processor 120 may supply a specified current to the thermoelectric cooler 350 to increase a temperature difference between the cold side 351 and the hot side 352.

The processor 120 may continuously measure the temperature of the heat generating element 330 when the measured temperature is below (or lower than or equal to) the reference temperature (NO in 430). The processor 120 may prevent heat generation due to operation of the thermoelectric cooler 350 at low temperatures by operating the thermoelectric cooler 350 only when the temperature is equal to or higher than (exceeds) the reference temperature.

In operation 450, the processor 120 may continuously measure the temperature of the heat generating element 330 to determine whether the temperature is below (or lower than or equal to) the reference temperature.

In operation 460, when the temperature is below (lower than or equal to) the reference temperature (YES in 450), the processor 120 may terminate the operation of the thermoelectric cooler 350. When the temperature is equal to or higher than (or exceeds) (NO in 450), the processor 120 may continue to drive the thermoelectric cooler 350.

According to one or more embodiments, the processor 120 may drive the thermoelectric cooler 350 when a specified application is executed or the electronic device 201 operates in a specified mode. For example, when a game application is running or a video is played, the processor 120 may drive the thermoelectric cooler 350 at a lower reference temperature.

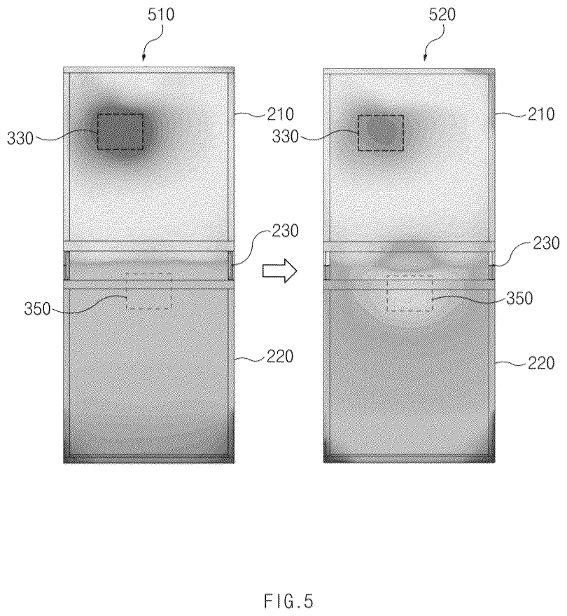

FIG. 5 illustrates a change in temperature distribution according to the operation of the thermoelectric cooler according to one or more embodiments.

Referring to FIGS. 2 and 5, the electronic device 201 may include the thermoelectric cooler 350. The thermoelectric cooler 350 may allow the heat generated from the heat generating element 330 included inside the first housing 210 to be easily transferred and diffused to the second housing 220.

In a first state 510 before the thermoelectric cooler 350 operates or is not in operation, a thermal spreading bottle neck may occur due to the hinge structure 230. Accordingly, the heat generated in the heat generating element 330 may be concentrated in the first housing 210 and may not spread to the second housing 220. The temperature on the surface around the heat generating element 330 may be equal to or higher than the reference temperature (e.g., 40). This may cause burns to the user and may cause malfunction due to damage to internal components.

In a second state 520 where the thermoelectric cooler 350 operates at a specified reference temperature (e.g., 40) or higher, the heat trapped in the first housing 210 may easily move toward the second housing 220. In this case, the temperature at a location of and near the heat generating element 330 included in the first housing 210 may be lower than the first state 510. The temperature of the second housing 220 may be higher than that of the first state 510. Thereby, a coefficient of thermal spreading (CTS), which is a ratio between the maximum temperature and the average temperature of the surface, may be increased.

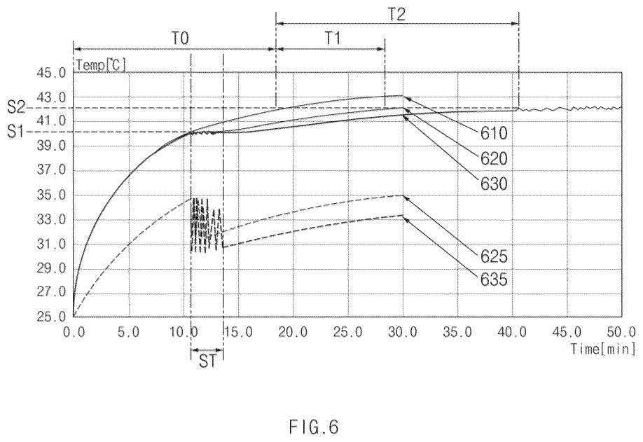

FIG. 6 shows graphs of temperature changes according to the operation of the thermoelectric cooler according to one or more embodiments.

Referring to FIGS. 1 to 3 and FIG. 6, the processor 120 may execute a specified function (e.g., video playback, game execution) using the heat generating element 330. The heat generating element 330 may be an application processor (AP) or a communication chip. For example, when a game application is continuously running, the surface temperature at a location of and near the heat generating element 330 may rise.

The processor 120 may set a reference temperature S1 for driving the thermoelectric cooler 350. For example, the processor 120 may set the reference temperature S1 for the surface temperature at a location of and near the heat generating element 330 to 40 degrees.

When the thermoelectric cooler 350 does not operate for the temperature rise of the heat generating element 330, the surface temperature may rise above the reference temperature S1 (graph 610). The processor 120 may stop the operation of the heat generating element 330 or generate a user notification when the surface temperature reaches or exceeds an internally set limit temperature S2 (e.g., 42 degrees). When the thermoelectric cooler 350 does not operate, the time for the surface temperature to reach the limit temperature S2 may be TO (e.g., 18.6 minutes).

The processor 120 may drive the thermoelectric cooler 350 when the surface temperature at a location of and near the heat generating element 330 is equal to or higher than the reference temperature S1 (e.g., 40 degrees). When the thermoelectric cooler 350 is driven, the time for the surface temperature to reach the limit temperature S2 may increase.

For example, when the measured surface temperature is higher than the specified reference temperature (e.g., 40 degrees), the processor 120 may drive the thermoelectric cooler 350 at a specified current value (e.g., 0.5 A). In an initial state section ST, the thermoelectric cooler 350 may be turned on and off repeatedly. In subsequent sections, the thermoelectric cooler 350 may gradually lower the surface temperature.

According to one or more embodiments, the performance of the thermoelectric cooler 350 may vary depending on the material properties or configuration of the thermoelectric cooler 350.

For example, in graphs 620 and 625 of the first thermoelectric cooler, the temperature of the cold side of the first thermoelectric cooler may be maintained to be lower than the reference temperature S1 (graph 625). By the operation of the first thermoelectric cooler, the heat transfer from the first housing 210 to the second housing 220 may be accelerated, and the surface temperature at a location of and near the heat generating element 330 may be lowered. When the first thermoelectric cooler is driven, the time for the surface temperature to reach the limit temperature S2 (e.g., 28.3 minutes) may increase from TO time (e.g., 18.6 minutes) to T1 time (e.g., about 10 minutes) (graph 620).

For another example, the second thermoelectric cooler may be a module with an improved cooling performance of 1 W compared to the first thermoelectric cooler, and may additionally cool the temperature of the cold side by an about 2 degrees. In the graphs 630 and 635 of the second thermoelectric cooler, the temperature of the cold side of the second thermoelectric cooler may be maintained to be lower than the reference temperature S1 (graph 635). By the operation of the second thermoelectric cooler, the heat transfer from the first housing 210 to the second housing 220 may be accelerated, and the surface temperature at a location of and near the heat generating element 330 may be lowered. The temperature of the cold side of the second thermoelectric cooler (graph 635) may be maintained to be lower than the temperature of the cold side of the first thermoelectric cooler (graph 625). When the second thermoelectric cooler is driven, the time for the surface temperature to reach the limit temperature S2 (e.g., 40.6 minutes) may increase from TO time (e.g., 18.6 minutes) to as much time as T2 (e.g., about 22 minutes) (graph 630).

According to one or more embodiments, a heat dissipation capacity (the amount of power that the system may consume based on a surface maximum temperature of 42 degrees) of the heat dissipation layer 301 may increase depending on the driving of the thermoelectric cooler 350. For example, the heat dissipation capacity of the heat dissipation layer 301 before the thermoelectric cooler 350 is driven may be 2.64 W. When the first thermoelectric cooler is driven, the heat dissipation capacity of the heat dissipation layer 301 may be 2.93 W, and when the first thermoelectric cooler is driven, the heat dissipation capacity of the heat dissipation layer 301 may be 3.05 W.

For example, when 30 minutes have passed since a time point at which the heat generating element 330 was driven, the performances of the first thermoelectric cooler and the second thermoelectric cooler may be as shown in [Table 1] below.

TABLE 1

| | Surface | Average | | Heat transfer rate |
|---|---|---|---|---|
| Results after | max | surface | | of heat dissipation |
| 30 minutes | temperature | temperature | CTS | structure |
| Non-operation | 43.1° C. | 35.4° C. | 0.57 | 0.32 W |
| TEC1 operated | 42.1° C. | 36.7° C. | 0.68 | 0.95 W |
| TEC2 operated | 41.5° C. | 36.4° C. | 0.70 | 1.14 W |
| Non-operation | 1.6↓ | 1.0↑ | 0.13↑ | 0.82 W↑ |
| preparation | | | | |
| TEC2 effect | | | | |

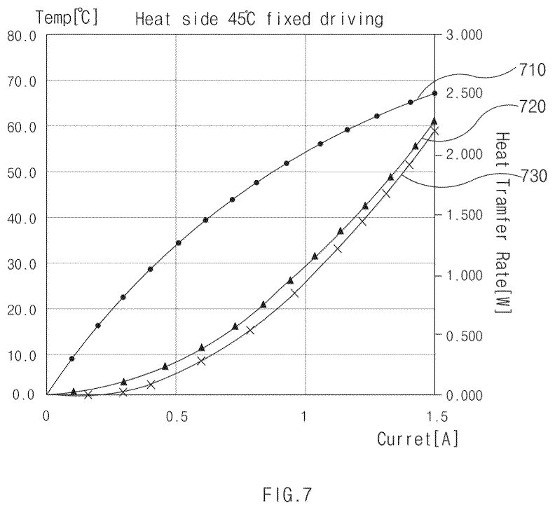

FIG. 7 illustrates a driving performance of the thermoelectric cooler according to one or more embodiments.

Referring to FIG. 7, a first graph 710 represents a temperature difference ΔT between the hot side and the cold side when the thermoelectric cooler 350 is driven while maintaining the temperature of the hot side of the thermoelectric cooler 350 at 45 degrees. As a current supplied to the thermoelectric cooler 350 increases, the temperature of the cold side may decrease and the temperature difference ΔT may increase.

A second graph 720 and a third graph 730 represent the amount of heat generated in each of the first thermoelectric cooler and the second thermoelectric cooler as the supplied current increases. As the supplied current increases, the amount of heat generated in the first thermoelectric cooler and the second thermoelectric cooler may increase. When a specified current value (e.g., 1 A) is exceeded, the amount of the generated heat rapidly increases, which may reduce the cooling efficiency of the first thermoelectric cooler or the second thermoelectric cooler.

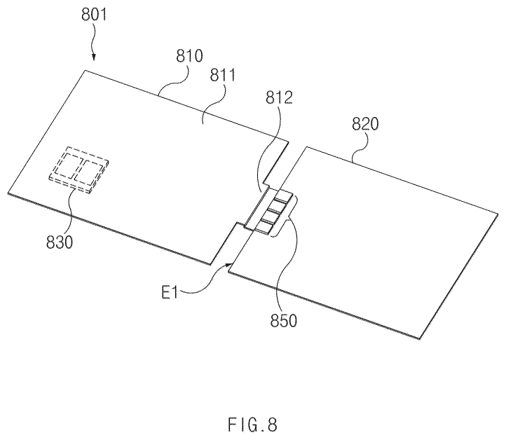

FIG. 8 illustrates a heat dissipation structure including a plurality of thermoelectric coolers according to one or more embodiments.

Referring to FIGS. 2 and 8, a heat dissipation structure 801 may include a first plate 810, a second plate 820, a heat generating element 830, and a plurality of thermoelectric coolers 850. The heat dissipation structure 801 may be included inside the electronic device 101 in FIG. 1 or the electronic device 201 in FIG. 2.

The features of the first plate 810, the second plate 820, and the heat generating element 830 may be the same as or similar to the features of the first plate 310, the second plate 320, and the heat generating element 330 in FIG. 3.

The plurality of thermoelectric coolers 850 may be included inside the second housing 220. The plurality of thermoelectric coolers 850 may be disposed in a row in a region corresponding to a connecting portion 812 among ends E1 of the second plate 320 (ends adjacent to the connecting portion 812). The width of the region where the plurality of thermoelectric coolers 850 are disposed may be smaller than or equal to the width of the connecting portion 812 of the first plate 810. A plate portion 811 and the connecting portion 812 of the first plate 810 may transfer heat generated in the heat generating element 330 to the plurality of thermoelectric coolers 850.

According to one or more embodiments, at least some of the plurality of thermoelectric coolers 850 may operate according to specified conditions. For example, when the plurality of thermoelectric coolers 850 include first to fourth thermoelectric coolers, the first thermoelectric cooler and the second thermoelectric cooler may be driven at a first reference temperature (e.g., 38 degrees), and the third thermoelectric cooler and the fourth thermoelectric cooler may be driven at a second reference temperature (e.g., 40 degrees), which is higher than the first reference temperature (e.g., 38 degrees).

In FIG. 8, a form in which the plurality of thermoelectric coolers 850 are disposed in one line (or row) is illustrated as an example, but embodiments of the disclosure are not limited thereto. For example, the plurality of thermoelectric coolers 850 may include first to eighth thermoelectric coolers. The first to fourth thermoelectric coolers may be disposed in a first row, and the fifth to eighth thermoelectric coolers may be disposed in a second row.

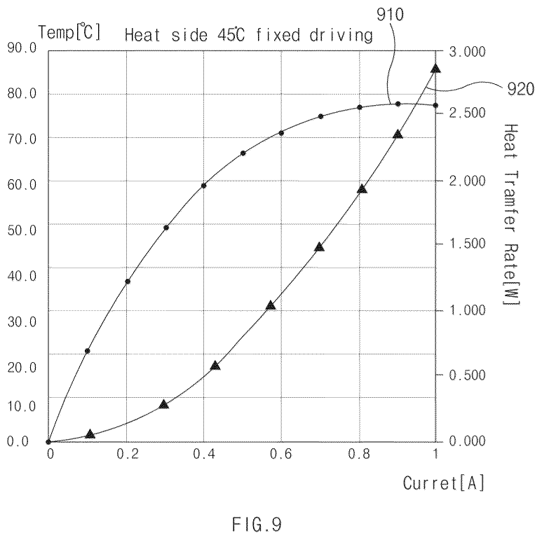

FIG. 9 illustrates a driving performance of the plurality of thermoelectric coolers according to one or more embodiments.

Referring to FIGS. 8 and 9, a first graph 910 represents a temperature difference ΔT between hot sides and cold sides when the plurality of thermoelectric coolers 850 are driven while maintaining the temperature of the hot sides of the thermoelectric coolers 850 at 45 degrees. As a current supplied to the plurality of thermoelectric coolers 350 increases, the temperature of the cold side may decrease and the temperature difference ΔT may increase. Compared to the first graph 710 in FIG. 7, even when the plurality of thermoelectric coolers 850 are driven with a small current value, the plurality of thermoelectric coolers 850 may exhibit a large heat transfer rate.

A second graph 920 shows the amount of heat generated in the plurality of thermoelectric coolers 850 as the supplied current increases. As the supplied current increases, the amount of heat generated in the plurality of thermoelectric coolers 850 may increase. When a specified current value (e.g., 0.5 A) is exceeded, the amount of the generated heat rapidly increases, which may reduce the cooling efficiency of the plurality of thermoelectric coolers 850.

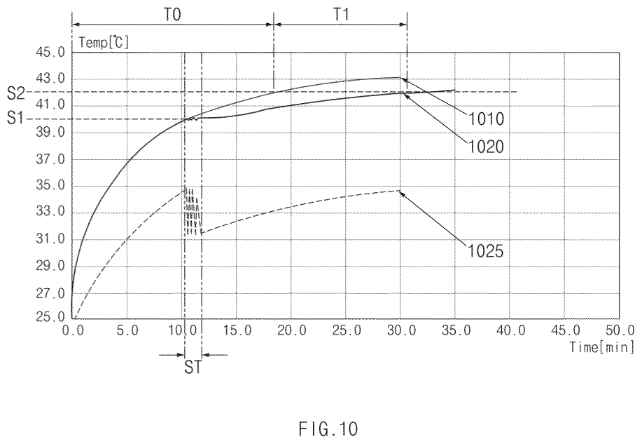

FIG. 10 shows graphs of temperature changes according to the operation of the plurality of thermoelectric coolers according to one or more embodiments.

Referring to FIGS. 1, 2, 8, and 10, the processor 120 may execute a specified function (e.g., video playback, game execution) using the heat generating element 830. The heat generating element 830 may be an application processor (AP) or a communication chip. For example, when a game application is continuously running, the surface temperature at a location of and near the heat generating element 830 may rise.

The processor 120 may set a reference temperature S1 for driving the plurality of thermoelectric coolers 850. For example, the processor 120 may set the reference temperature S1 for the surface temperature at a location of and near the heat generating element 830 to 40 degrees.

When the plurality of thermoelectric coolers 850 do not operate for the temperature rise of the heat generating element 830, the surface temperature may rise above the reference temperature S1 (graph 1010). The processor 120 may stop the operation of the heat generating element 830 or generate a user notification when the surface temperature reaches or exceeds an internally set limit temperature S2 (e.g., 42 degrees). When the plurality of thermoelectric coolers 850 do not operate, the time for the surface temperature to reach the limit temperature S2 may be TO (e.g., 18.6 minutes).

The processor 120 may drive the plurality of thermoelectric coolers 850 when the surface temperature at a location of and near the heat generating element 830 is equal to or higher than the reference temperature S1 (e.g., 40 degrees). When the plurality of thermoelectric coolers 350 are driven, the time for the surface temperature to reach the limit temperature S2 may increase.

The processor 120 may drive the plurality of thermoelectric coolers 850 at a specified current value (e.g., 0.1 A) when the surface temperature at a location of and near the heat generating element 830 exceeds the specified reference temperature S1 (e.g., 40 degrees). In an initial state section ST, the plurality of thermoelectric coolers 850 may be turned on and off repeatedly. In subsequent sections, the plurality of thermoelectric coolers 850 may gradually lower the surface temperature.

In graphs 1020 and 1025 of the plurality of thermoelectric coolers 850, the temperature of the cold side of the plurality of thermoelectric coolers 850 may be maintained to be lower than the reference temperature S1 (graph 1025). The movement of heat from the first housing 210 to the second housing 220 may be accelerated by the operation of the plurality of thermoelectric coolers 850, and the surface temperature at a location of and near the heat generating element 830 may be lowered. When the plurality of thermoelectric coolers 850 are driven, the time for the surface temperature to reach the limit temperature S2 (e.g., 31.3 minutes) may increase from T0 time (e.g., 18.6 minutes) to as much time as T1 (e.g., about 12.7 minutes).

According to one or more embodiments, a heat dissipation capacity (the amount of power that the system may consume based on a surface maximum temperature of 42 degrees) of the heat dissipation structure 801 may increase depending on the driving of the plurality of thermoelectric coolers 850. For example, the heat dissipation capacity of the heat dissipation structure 801 before the plurality of thermoelectric coolers 850 are driven may be 2.64 W. When the plurality of thermoelectric coolers 850 are driven, the heat dissipation capacity of the heat dissipation layer 301 may be 2.9 W.

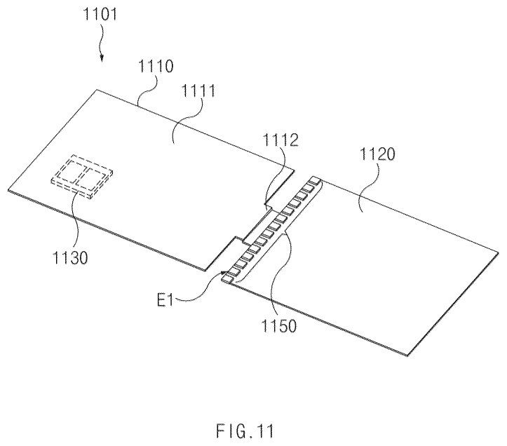

FIG. 11 illustrates a heat dissipation structure including a plurality of thermoelectric coolers with an expanded disposition region according to one or more embodiments.

Referring to FIGS. 2 and 11, a heat dissipation structure 1101 may include a first plate 1110, a second plate 1120, a heat generating element 1130, and a plurality of thermoelectric coolers 1150. The heat dissipation structure 1101 may be included inside the electronic device 101 in FIG. 1 or the electronic device 201 in FIG. 2.

The features of the first plate 1110, the second plate 1120, and the heat generating element 1130 may be the same as or similar to the features of the first plate 310, the second plate 320, and the heat generating element 330 in FIG. 3.

The plurality of thermoelectric coolers 1150 may be included inside the second housing 220. The plurality of thermoelectric coolers 1150 may be disposed in a row along an end E1 of the second plate 320 (an end adjacent to a connecting portion 1112). Unlike FIG. 8, a width at which the plurality of thermoelectric coolers 1150 are disposed may be larger than a width of the connecting portion 1112 of the first plate 1110, and may be disposed to correspond to the entire end E1 (the end adjacent to the connecting portion 1112) of the second plate 320. A plate portion 1111 and the connecting portion 1112 of the first plate 1110 may transfer heat generated in the heat generating element 330 to the plurality of thermoelectric coolers 1150.

According to one or more embodiments, at least some of the thermoelectric coolers 1150 may operate according to specified conditions. For example, when the plurality of thermoelectric coolers 1150 include first to fourteenth thermoelectric coolers, the first to seventh thermoelectric coolers may be driven at a first reference temperature (e.g., 38 degrees), and the eighth to fourteenth thermoelectric coolers may be driven at a second reference temperature (e.g., 40 degrees), which is higher than the first reference temperature (e.g., 38 degrees).

In FIG. 11, a form in which the plurality of thermoelectric coolers 1150 are disposed in one line (or row) is illustrated as an example, but embodiments of the disclosure are not limited thereto. For example, the plurality of thermoelectric coolers 1150 may include first to twenty-eighth thermoelectric coolers. The first to fourteenth thermoelectric coolers may be disposed in a first row, and the fifteenth to twenty-eighth thermoelectric coolers may be disposed in a second row.

An electronic device (101; 201) according to one or more embodiments may include a first housing (210), a second housing (220), a hinge structure (230), an electrical element (330; 830; 1130) included inside the first housing (210), a first plate (310; 810; 1110) included inside the first housing (210) and contacting one surface of the electrical element (330; 830; 1130), at least one thermoelectric cooler (350; 850; 1150) included inside the second housing (220) and having a cold side in contact with the first plate (310; 810; 1110), a second plate (320; 820; 1120) included inside the second housing (220) and contacting a hot side of the thermoelectric cooler, and a processor (120). The processor (120) may execute instructions of the memory (130) to measure a temperature at a specified point of the electrical element (330; 830; 1130) or at one or more specific locations of the first housing (210) at which the electrical element (330; 830; 1130) is located, the one or more specific locations comprising at least one of a specific location of the electrical element (330; 830; 1130) with respect to the first housing (210) or one or more locations adjacent to the specific location of the electrical element (330; 830; 1130) with respect to the first housing (210). The processor (120) may execute instructions of the memory (130) to drive the thermoelectric cooler based on the measured temperature so that heat generated in the electrical element (330; 830; 1130) moves to the second plate (320; 820; 1120) and is dissipated.

According to one or more embodiments, the processor (120) may execute instructions of the memory (130) to drive the thermoelectric cooler by comparing a preset reference temperature with the measured temperature.

According to one or more embodiments, the first plate (310; 810; 1110) may include a plate portion (311; 811; 1111) that contacts one surface of the electrical element (330; 830; 1130) and a connecting portion (312; 812; 1112) that extends from the plate portion (311; 811; 1111) to contact the cold side.

According to one or more embodiments, the connecting portion (312; 812; 1112) may include a step structure. The plate portion (311; 811; 1111) and the second plate (320; 820; 1120) may be disposed on the same plane by the step structure.

According to one or more embodiments, a width of the connecting portion (312; 812; 1112) may be smaller than a width of the plate portion (311; 811; 1111).

According to one or more embodiments, the at least one thermoelectric cooler (350; 850; 1150) may include a plurality of thermoelectric coolers.

According to one or more embodiments, the first plate (310; 810; 1110) may include a plate portion (311; 811; 1111) that contacts one surface of the electrical element (330; 830; 1130) and a connecting portion (312; 812; 1112) that extends from the plate portion (311; 811; 1111) to contact the cold side. The plurality of thermoelectric coolers may be disposed in a region corresponding to the connecting portion (312; 812; 1112).

According to one or more embodiments, the plurality of thermoelectric coolers may be disposed in a region corresponding to an entire end adjacent to the hinge structure 230 in the second plate (320; 820; 1120).

According to one or more embodiments, the plurality of thermoelectric coolers may be disposed in a plurality of lines.

According to one or more embodiments, the processor (120) may execute instructions of the memory (130) to drive some of the plurality of thermoelectric coolers by comparing a first reference temperature with the measured temperature. The processor (120) may execute instructions of the memory (130) to drive other some of the plurality of thermoelectric coolers by comparing a second reference temperature with the measured temperature.

According to one or more embodiments, the processor (120) may execute instructions of the memory (130) to drive the thermoelectric cooler when a specified application is executed.

An electronic device (101; 201) according to one or more embodiments may include a first housing (210), a second housing (220), a hinge structure (230), an electrical element (330; 830; 1130) included inside the first housing (210), a heat dissipation structure (301; 801; 1101) configured to dissipate heat generated in the electrical element (330; 830; 1130), a memory (130), and a processor (120).

According to one or more embodiments, the heat dissipation structure (301; 801; 1101) may be included inside the first housing (210). The heat dissipation structure (301; 801; 1101) may include a first plate (310; 810; 1110) contacting one surface of the electrical element (330; 830; 1130), at least one thermoelectric cooler (350; 850; 1150) included inside the second housing (220) and having a cold side in contact with the first plate (310; 810; 1110), and a second plate (320; 820; 1120) included inside the second housing (220) and contacting a hot side of the thermoelectric cooler. The processor (120) may execute instructions of the memory (130) to measure a temperature at a specified point of the electrical element (330; 830; 1130) or the first housing (210) around the electrical element (330; 830; 1130). The processor (120) may execute instructions of the memory (130) to drive the thermoelectric cooler based on the measured temperature so that heat generated in the electrical element (330; 830; 1130) moves to the second plate (320; 820; 1120) and is dissipated.

According to one or more embodiments, the processor (120) may drive the thermoelectric cooler by comparing a preset reference temperature with the measured temperature.

According to one or more embodiments, the first plate (310; 810; 1110) may include a plate portion (311; 811; 1111) that contacts one surface of the electrical element (330; 830; 1130) and a connecting portion (312; 812; 1112) that extends from the plate portion (311; 811; 1111) to contact the cold side.

According to one or more embodiments, the connecting portion (312; 812; 1112) may include a step structure. The plate portion (311; 811; 1111) and the second plate (320; 820; 1120) may be disposed on the same plane by the step structure.

According to one or more embodiments, a width of the connecting portion (312; 812; 1112) may be smaller than a width of the plate portion (311; 811; 1111).

According to one or more embodiments, the at least one thermoelectric cooler (350; 850; 1150) may include a plurality of thermoelectric coolers.

According to one or more embodiments, the first plate (310; 810; 1110) may include a plate portion (311; 811; 1111) that contacts one surface of the electrical element (330; 830; 1130) and a connecting portion (312; 812; 1112) that extends from the plate portion (311; 811; 1111) to contact the cold side. The plurality of thermoelectric coolers may be disposed in a region corresponding to the connecting portion (312; 812; 1112).

According to one or more embodiments, the plurality of thermoelectric coolers may be disposed in a region corresponding to the entire end adjacent to the hinge structure 230 in the second plate (320; 820; 1120).

According to one or more embodiments, the plurality of thermoelectric coolers may be disposed in a plurality of lines.

An electronic device according to one or more embodiments disclosed herein may easily transfer heat generated in an electrical component to a housing on the opposite side of a hinge structure using a thermoelectric cooler. In this way, it is possible to protect users and prevent malfunctions caused by damage to internal components of the electronic device.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to one or more embodiments, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to one or more embodiments, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While embodiments of the disclosure have been illustrated and described, it will be understood that the embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiments described herein may be used in conjunction with any other embodiments described herein.

What is claimed is:

1. An electronic device comprising:
a first housing;
a second housing;
a hinge connecting the first housing and the second housing to be foldable relative to each other;
an electrical element inside the first housing;
a first plate inside the first housing and contacting a surface of the electrical element;
at least one thermoelectric cooler inside the second housing and comprising a cold side contacting the first plate;
a second plate inside the second housing and contacting a hot side of the at least one thermoelectric cooler;
memory storing one or more instructions; and
one or more processors configured to execute the one or more instructions to:
measure a temperature at a specified point of the electrical element or at one or more specific locations of the first housing at which the electrical element is located; and
drive the at least one thermoelectric cooler based on the measured temperature to move heat generated in the electrical element to the second plate.

2. The electronic device of claim 1, wherein the one or more processors are further configured to execute the one or more instructions to drive the at least one thermoelectric cooler based on a preset reference temperature compared to the temperature.

3. The electronic device of claim 1, wherein the first plate comprises:
a plate portion contacting the surface of the electrical element; and
a connecting portion extending from the plate portion and contracting the cold side of the at least one thermoelectric cooler.

4. The electronic device of claim 3, wherein the connecting portion comprises a step, and
wherein the plate portion and the second plate are on a same plane via the step.

5. The electronic device of claim 3, wherein a width of the connecting portion is less than a width of the plate portion.

6. The electronic device of claim 1, wherein the at least one thermoelectric cooler comprises a plurality of thermoelectric coolers.

7. The electronic device of claim 6, wherein the first plate comprises:
a plate portion contacting the one surface of the electrical element; and
a connecting portion extending from the plate portion and contacting the cold side, and
wherein the plurality of thermoelectric coolers are in a region corresponding to the connecting portion.

8. The electronic device of claim 6, wherein the plurality of thermoelectric coolers are in a region corresponding to an entire end of the second plate adjacent to the hinge in the second plate.

9. The electronic device of claim 6, wherein the plurality of thermoelectric coolers are in a plurality of lines.

10. The electronic device of claim 6, wherein the one or more processors are further configured to execute the one or more instructions to:
drive some of the plurality of thermoelectric coolers based on a first reference temperature compared to the temperature; and
drive other of the plurality of thermoelectric coolers based on a second reference temperature compared to the temperature.

11. The electronic device of claim 1, wherein the one or more processors are further configured to execute the one or more instructions to drive the at least one thermoelectric cooler in a state in which a specified application is executed by the electronic device.

12. An electronic device comprising:
a first housing;
a second housing;
a hinge connecting the first housing and the second housing to be foldable relative to each other;
an electrical element inside the first housing;
a heat dissipation layer configured to dissipate heat generated in the electrical element;
a memory comprising one or more instructions; and
one or more processors configured to execute the one or more instructions,
wherein the heat dissipation layer comprises:
a first plate inside the first housing and contacting a surface of the electrical element;
at least one thermoelectric cooler inside the second housing and comprising a cold side contacting the first plate; and
a second plate inside the second housing and contacting a hot side of the at least one thermoelectric cooler, and
wherein one or more processors are further configured to execute the one or more instructions to:
measure a temperature at a specified point of the electrical element or at one or more specific locations of the first housing at which the electrical element is located; and
drive the at least one thermoelectric cooler based on the temperature to move heat generated in the electrical element to the second plate.

13. The electronic device of claim 12, wherein the one or more processors are further configured to execute the one or more instructions to drive the at least one thermoelectric cooler based on a preset reference temperature compared to the temperature.

14. The electronic device of claim 12, wherein the first plate comprises:
a plate portion contacting the surface of the electrical element; and
a connecting portion extending from the plate portion and contacting the cold side of the at least one thermoelectric cooler.

15. The electronic device of claim 14, wherein the connecting portion includes a step structure, and
wherein the plate portion and the second plate are arranged on the same plane by the step structure.

16. The electronic device of claim 14, wherein a width of the connecting portion is smaller than a width of the plate portion.

17. The electronic device of claim 12, wherein the at least one thermoelectric cooler comprises a plurality of thermoelectric coolers.

18. The electronic device of claim 17, wherein the first plate includes a plate portion contacting a surface of the electrical element, and a connecting portion extending from the plate portion and contacting the cooling surface, and
wherein the plurality of thermoelectric coolers are arranged in an area corresponding to the connecting portion.

19. The electronic device of claim 17, wherein the plurality of thermoelectric coolers are arranged in an area corresponding to an end of the second plate adjacent to the hinge structure.

20. The electronic device of claim 17, wherein the plurality of thermoelectric coolers are arranged in a plurality of lines.
